(19) United States
(12) Patent Application Publication
(10) Pub. No.: US 2011/0198572 A1
(43) Pub. Date: Aug. 18, 2011

(54) ORGANIC LIGHT EMITTING DIODE DISPLAY AND METHOD FOR MANUFACTURING THE SAME

(75) Inventors: Sun Park, Yongin-City (KR); Yul-Kyu Lee, Yongin-City (KR)

(73) Assignee: Samsung Mobile Display Co., Ltd.

(21) Appl. No.: 13/020,536

(22) Filed: Feb. 3, 2011

(30) Foreign Application Priority Data
Feb. 12, 2010 (KR) 2010-0013610

(51) Int. Cl. H01L 51/52; H01L 51/56

(52) U.S. Cl. 257/40; 438/34; 257/E51.018

(57) ABSTRACT

An OLED display having an improved pad area, and a manufacturing method thereof. The OLED display includes a substrate including a display area and a pad area, an organic light emitting element formed in the display area, a plurality of pads formed in the pad area, and receiving an external signal for light emission of the organic light emitting element and transmitting the signals to the organic light emitting element, and a planarization layer insulating the pads. The planarization layer includes a recess portion formed between the pads.

### CLAIM OF PRIORITY

This application makes reference to, incorporates into this specification the entire contents of, and claims all benefits accruing under 35 U.S.C. §119 from an application earlier filed in the Korean Intellectual Property Office on Feb. 12, 2010, and there duly assigned Serial No. 10-2016-0013610.

### BACKGROUND OF THE INVENTION

1. Field of the Invention

The described technology relates generally to an organic light emitting diode (OLED) display and a manufacturing method thereof, and more particularly the described technology relates to an OLED display having an improved pad area and a manufacturing method thereof.

2. Description of the Related Art

An organic light emitting diode (OLED) display device is used to display visual images.

### SUMMARY OF THE INVENTION

It is therefore an aspect of the present invention to provide an improved organic light emitting diode (OLED) display.

It is another aspect of the present invention to provide an organic light emitting diode (OLED) display having an advantage of preventing a short-circuit of pads when the pads are corroded, and a manufacturing method thereof.

According to one or more embodiments of the present invention, an OLED display may be constructed with a substrate including a display area and a pad area, an organic light emitting element formed in the display area, a plurality of pads formed in the pad area, and receiving an external signal for light emission of the organic light emitting element and transmitting the signal to the organic light emitting element, and a planarization layer insulating the pads. The planarization layer may include a recess portion formed between the pads.

The recess portion may have a line shape extending along a length direction of one the pads. The recess portion may be formed singularly or in plural between neighboring pads. Alternatively, the recess portion may extend along three sides of the pad.

The recess portion may he formed penetrating the planarization layer.

The OLED display may further include a thin film transistor formed on the display area and including a semiconductor layer, a gate electrode, a source electrode, and a drain electrode. The organic light emitting element may include a pixel electrode connected to the drain electrode through a first contact hole of the planarization layer. The pad may include a first pad layer formed at the same layer where the source and drain electrode are formed and a second pad layer formed at the same layer where the pixel electrode is formed.

The planarization hole may include a second contact hole exposing the first pad layer, and the second pad layer may be formed on the first pad layer exposed by the second contact hole.

The OLED display may further include a pixel defining layer having an opening that exposes the pixel electrode. The pixel defining layer may fill the recess portion of the planarization layer.

The second pad layer may include at least one selected from a group consisting of aluminum, silver, palladium, and copper.

According to another embodiment of the present invention, a manufacturing method of an OLED display may contemplate preparing a substrate body including a display area and a pad area, forming a source electrode and a drain electrode of a thin film transistor in the display area and a first pad layer in the pad area, forming a planarization layer covering the source electrode, the drain electrode, and the first pad layer, forming first and second contact holes respectively exposing the drain electrode and the first pad layer in the planarization layer, and forming a pixel electrode and a second pad layer respectively on the first contact hole and the second contact hole. The forming of the first and second contact holes includes forming a recess portion between the first pads in the planarization layer.

The first contact hole, the second contact hole, and the recess portion may be formed together through a process using a single mask.

After the forming of the pixel electrode and the second pad layer, the manufacturing method may further include forming a pixel defining layer having an opening that exposes the pixel electrode and the second pad layer and sequentially forming an organic emission layer and a common electrode on the opening of the pixel defining layer. The pixel defining layer fills the recess portion of the planarization layer.

The second pad layer may include at least one selected from a group consisting of aluminum, silver, palladium, and copper.

In the OLED display according to the exemplary embodiment, the recess portion formed in the planarization layer functions as a barrier preventing a movement of byproducts generated by a corrosion of the pads so that short-circuit between neighboring pads can be prevented. Accordingly, reliability of the OLED display can be improved.

According to the manufacturing method of the OLED display of the exemplary embodiment forms the recess portion formed in the planarization layer when the first and second contact holes are formed so that the OLED display that can prevent short-circuit between pads can be manufactured without a separate mask or an additional process. That is, an OLED display having improved reliability can be manufactured through a simple manufacturing process.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a top plan view of an Organic light emitting diode (OLED) display constructed as an exemplary embodiment according to the principles of the present invention;

FIG. 2 is an enlarged top plan view of area A of FIG. 1;

FIG. 3 is a cross-sectional view of the display area of FIG. 2 taken along the line III″-III′″, and the pad area of FIG. 1 taken along the line III-III′;

FIG. 4A is a plan view of pads and recess portions constructed as an exemplary embodiment according to the principles of the present invention;

FIG. 4B is a plan view of pads and recess portions constructed as another exemplary embodiment according to the principles of the present invention;

FIG. 4C is a plan view of pads and recess portions constructed as still another exemplary embodiment according to the principles of the present invention;

FIG. 5 is a flowchart of a manufacturing method of the OLED display as an exemplary embodiment according to the principles of the present invention; and

FIG. 6 is a cross-sectional view of an OLED display during a process for forming first and second contact holes and a recess portion in a planarization layer in the manufacturing method of the OLED display as the exemplary embodiment according to the principles of the present invention.

### DETAILED DESCRIPTION OF THE INVENTION

An active matrix-type organic light emitting diode (OLED) display may be constructed with an organic light emitting diode (OLED) having a positive electrode (hole injection electrode), an organic emission layer, a negative electrode (electron injection electrode), and a thin film transistor driving the OLED. Holes from the positive electrode and electrons from the negative electrode are combined within the organic emission layer so as to form excitons being electron-hole pairs, and when the excitons return to a ground state, energy is generated to thereby emit light. With such light emission, the OLED display displays images.

The OLED display includes a display area where an image is displayed and a non-display area located around the display area. The non-display area includes a pad area where pads are formed. The pads are exposed to an exterior of the OLED display for connection with an external circuit such that the pads may be corroded due to an external environment. Byproducts from the corrosion of the pads may undesirably move, and thus causing the pads to be short circuited. In order to prevent this, the pads are formed with a material having strong corrosion resistance and this may cause deterioration of the light emission characteristic and increase the cost.

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention. Parts that are irrelevant to the description are omitted in order to clearly describe the exemplary embodiments of the present invention, and like reference numerals designate like elements throughout the specification.

In the drawings, the sizes and thicknesses of the components are merely shown for convenience of explanation, and therefore the present invention is not necessarily limited to the illustrations described and shown. herein. In the drawings, the thickness of layers, films, panels, regions, etc., are exaggerated for clarity.

When it is described that one element such as a layer, a film, an area, a plate, etc. is formed on another element, it means that one element exists right on another element or that one element exists on another element with a further element therebetween. In contrast, when an element is referred to as being “directly on” another element, there are no intervening elements present.

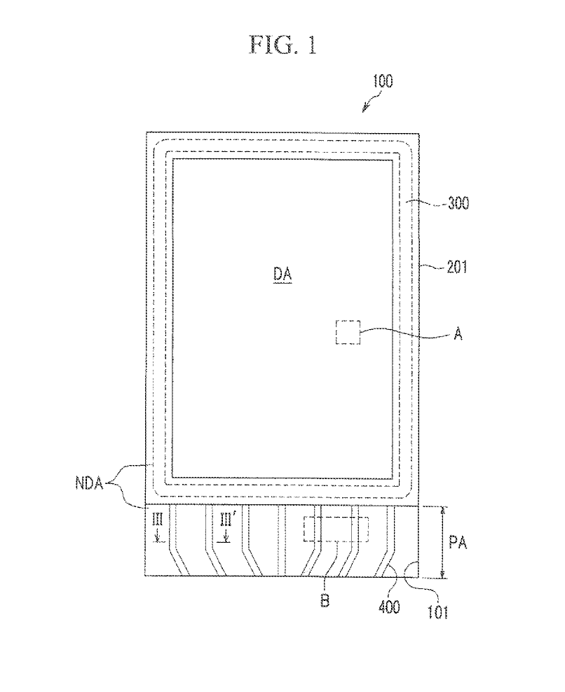

Referring to FIG. 1, an organic light emitting diode (OLED) display constructed as an exemplary embodiment according to the principles of the present invention will be described. FIG. 1 is a top plan view of the OLED display constructed as the exemplary embodiment.

Referring to FIG. 1, an OLED display 100 constructed as the present exemplary embodiment includes a first substrate (hereinafter referred to as a substrate) 101, a second substrate (hereinafter referred to as an encapsulation substrate) 201, and a sealing member 300. The present invention is, however, not limited thereto. That is, substrate 101 may be encapsulated not by encapsulation substrate 201 but by an encapsulation film.

Substrate 101 includes a display area DA where an image is displayed by light emission and a non-display area NDA located at edges of display area DA. An organic light emitting element, and a thin film transistor and wires for driving the organic light emitting element, are formed in display area DA. Non-display area NDA includes a pad area PA where a plurality of pads 400 are formed. The plurality of pads 400 receive an external signal for light emission of the organic light emitting element and transmit the external signal to the organic light emitting element.

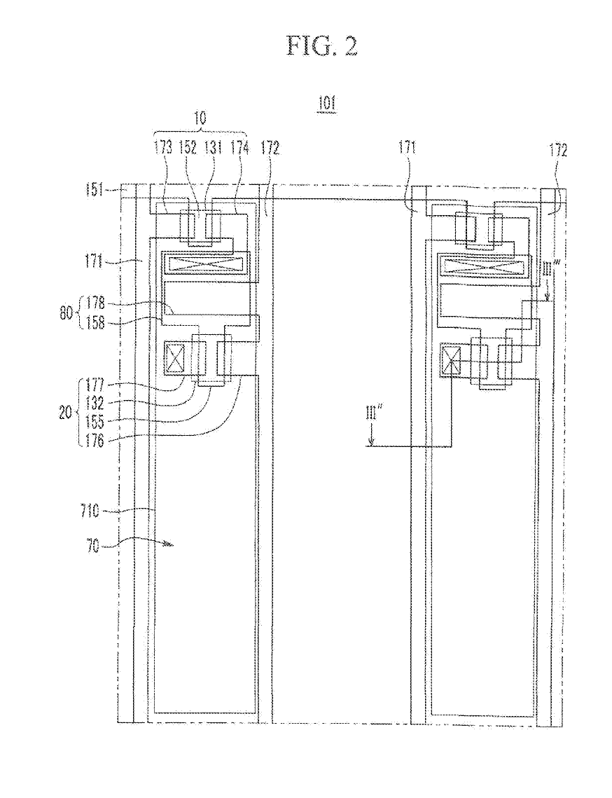

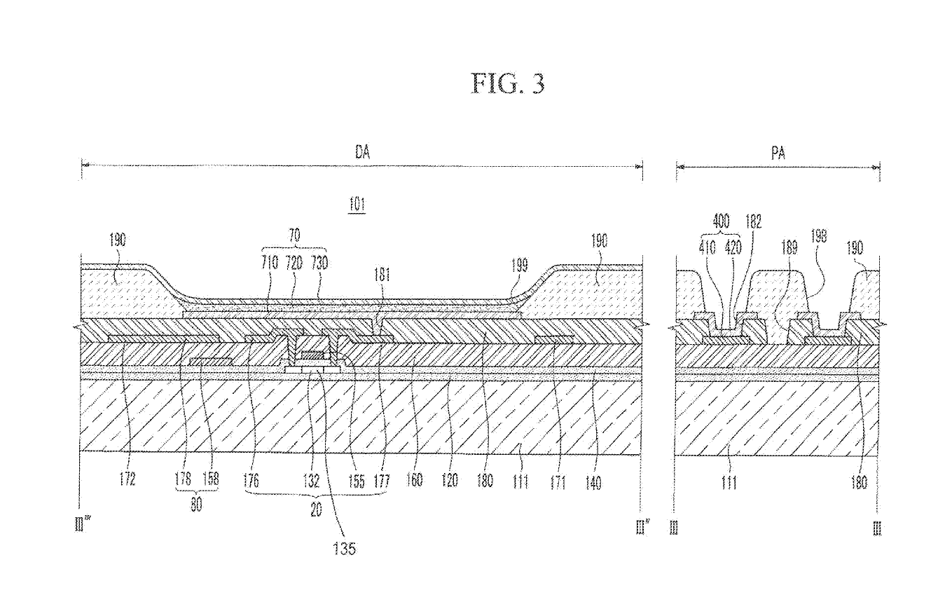

Referring to FIG. 2 and FIG. 3, display area DA and pad area PA constructed as the present exemplary embodiment according to the principles of the present invention will now be described in detail. FIG. 2 is an enlarged top plan view of portion A of FIG. 1, and FIG. 3 shows a cross-sectional view of the pad area of FIG. 1 taken along line III-III′, and a cross-sectional view of the display area of FIG. 2 taken along the line III″-III′″.

In the drawing, an active matrix (AM) type of OLED display with a 2Tr-1Cap structure in which a single pixel of display area DA (refer to FIG. 1) has two thin film transistors (TFTs) and one storage capacitor is illustrated, but the present invention is not meant to be limited thereto. That is, in the OLED display, a single pixel may have three or more TFTs and two or more storage capacitors, and the OLED display may have various other structures with more wiring. Here, a pixel refers to a minimum unit for displaying an image, and the OLED display displays an image through a plurality of pixels.

Referring to FIG. 2 and FIG. 3, substrate 101 of the present exemplary embodiment includes a switching thin film transistor 10, a driving thin film transistor 20, a capacitor 80, and an organic light emitting diode (OLED) 70 formed at each of a plurality of pixels defined in a substrate body 111. In addition, substrate 101 further 112 includes gate lines 151 arranged along one direction, and data lines 171 and common power lines 172 crossing gate lines 151 in an insulated manner.

Here, each pixel may be defined by gate lines 151, data lines 171, and common power lines 172, but it is not limited thereto.

OLED 70 includes a pixel electrode 710, an organic emission layer 720 formed on pixel electrode 710, and a common electrode 730 formed on organic emission layer 720. One or more pixel electrodes 710 are formed at each pixel, and therefore substrate 101 includes a plurality of pixel electrodes 710 respectively distanced from each other.

Pixel electrode 710 is a positive electrode which is a hole injection electrode, and common electrode 730 is a negative electrode which is an electron injection electrode. The present invention is, however, not limited thereto, and pixel electrode 710 may he a negative electrode and common electrode 730 may be a positive electrode according to a driving method of the OLED display.

When excitons being combinations of the holes and electrons injected into organic emission layer 720 fall from an excited state to a ground state, OLED 70 emits light.

Capacitor 80 includes a pair of capacitor plates 158 and 178 disposed interposing an interlayer insulation layer 160. Here, interlayer insulation layer 160 is a dielectric material. Charges charged in capacitor 80 and a voltage between the pair of capacitor plates 158 and 178 determine capacitance.

Switching thin film transistor 10 includes a switching semiconductor layer 131, a switching gate electrode 152, a switching source electrode 173, and a switching drain electrode 174. Driving thin film transistor 20 includes a driving semiconductor layer 132, a driving gate electrode 155, a driving source electrode 176, and a driving drain electrode 177.

Switching thin film transistor 10 is used as a switch for selecting a pixel for light emission. Switching gate electrode 152 is connected to gate lines 151, and switching source electrode 173 is connected to data lines 171. Switching drain electrode 174 is distanced from switching source electrode 173 and is connected to one capacitor plate 158.

Driving thin film transistor 20 applies driving power to pixel electrode 710 for light emission of organic emission layer 720 of OLED 70 in the selected pixel. Driving gate electrode 155 is connected to capacitor 158 that is connected with switching drain electrode 174. Driving source electrode 176 and the other capacitor plate 178 are respectively connected to common power lines 172. Driving drain electrode 177 is connected to pixel electrode 710 of OLED 70 through a first contact hole 181.

With such a structure, switching thin film transistor 10 transmits a data voltage applied to data line 171 to driving thin film transistor 20 by a data voltage applied to gate line 151. A voltage corresponds to a voltage difference of a common voltage transmitted from common power line 172 to driving thin film transistor 20 and the data voltage transmitted from switching thin film transistor 10 is stored in capacitor 80, and a current corresponding to the voltage stored in capacitor 80 flows to OLED 70 through driving thin film transistor 20 such OLED 70 emits light.

Referring to FIG. 2 and FIG. 3, display area DA and pad area PA of the present exemplary embodiment will now be described in further detail.

Since FIG. 3 illustrates OLED 70, driving thin film transistor 20, capacitor 80, data line 171, and common power line 172, description will be focused thereon. Since switching semiconductor layer 131, switching gate electrode 152, and switching source and drain electrodes 173 and 174 of switching thin film transistor 10 have the same structures as of driving semiconductor layer 132, driving gate electrode 155, and driving source and drain electrodes 176 and 177 of driving thin film transistor 20, no further description will be provided.

In the present exemplary embodiment, substrate body 111 may be formed of an insulating substrate made of glass, quartz, ceramic, or plastic. Since the present invention is not limited thereto, substrate body 111 may be, however, formed of a metallic substrate made of stainless steel.

A buffer layer 120 is formed on substrate body 111. Buffer layer 120 has roles of flattening the surface thereof and preventing intrusion of impure elements, and may be formed with various materials that are appropriate for the roles thereof. For example, buffer layer 120 may be formed with at least one material selected from silicon nitride (SiNx), silicon oxide (SiO2), and silicon oxynitride (SiOxNy). Buffer layer 120 is not, however, necessarily required, and hence may he omitted depending upon the kind of substrate body 111 and the processing conditions.

In display area DA, driving semiconductor layer 132 is formed on buffer layer 120. Driving semiconductor layer 132 may be formed with various semiconductor materials such as a polysilicon film or amorphous silicon film.

A gate insulation layer 140 formed with silicon nitride (SiNx) or silicon oxide (SiO2) is formed on driving semiconductor layer 132. Driving gate electrode 155, gate lines 151 (refer to FIG. 2), and first capacitor plate 158 are formed on gate insulation layer 140. Driving gate electrode 155 partially overlaps driving semiconductor layer 132. In further detail, driving gate electrode 155 overlaps a channel area 135 of driving semiconductor layer 132.

Interlayer insulation layer 160 that covers driving gate electrode 155 is formed on gate insulation layer 140. Like gate insulating layer 140, interlayer insulation layer 160 is formed with silicon nitride (SiNx) or silicon oxide (SiO2). Gate insulation layer 140 and interlayer insulation layer 160 have contact holes that expose source and drain areas of driving semiconductor layer 132.

In display area DA, driving source electrode 176, driving drain electrode 177, data line 171, common power line 172, and second capacitor plate 178 are formed on interlayer insulation layer 160. Driving source electrode 176 and driving drain electrode 177 are respectively connected with a source area and a drain area of driving semiconductor layer 132 through the contact holes.

Thus, driving thin film transistor 20 including driving semiconductor layer 132, driving gate electrode 155, driving source electrode 176, and driving drain electrode 177 is formed in display area DA. The configuration of driving thin film transistor 20 can be, however, variously modified.

In pad area PA, a first pad layer 410 forming pads 400 is formed on interlayer insulation layer 160. First pad layer 410 may be formed through the same process as of driving source electrode 176 and driving drain electrode 177 in display area DA, and may be formed with the same material as the same layer with driving source electrode 176 and driving drain electrode 177.

A planarization layer 180 covering driving source electrode 176, driving drain electrode 177, and first pad layer 410 is formed on interlayer insulation layer 160. Planarization layer 180 may be formed with an organic material such as a polyacryl-based material or a polyamide-based material.

Planarization layer 180 includes a first contact hole 181 exposing driving drain electrode 177 and a contact hole 182 exposing first pad layer 410. In planarization layer 180, a recess portion 189 is formed between first pad layers 410 of respective pads 400.

When first pad layer 410 and a second pad layer 420 formed on first pad layer 410 are corroded, recess portion 189 prevents byproducts of the corrosion of pad 400 from moving and being connected with a neighboring pad 400.

That is, conventionally, no recess portion 189 is provided and thus a flat side exists between pads 400. In this case, byproducts of corrosion of pad 400 may move along the flat side and this may cause a short-circuit of neighboring pads 400. In order to prevent this, pad 400 may be formed with a material having corrosion resistance and this undesirably causes a cost increase.

On the contrary, in the present exemplary embodiment according to the principles of the present invention, a step formed by recess portion 189 functions as a wall that prevents movement of corrosion byproducts so that neighboring pads 400 can hardly be connected with each other. Accordingly, short-circuit of pads 400 can be prevented and thus reliability of OLED display 100 can be improved.

Recess portion 189 can be formed through the process that forms first and second contact holes 181 and 182 of planarization layer 180, and therefore recess portion 189 can be formed without an additional mask or an additional process according to the present exemplary embodiment.

In the drawing, recess portion 189 penetrates planarization layer 180 and thus interlayer insulation layer 160 is exposed by recess portion 189, but the present invention is not limited thereto. If the depth of recess portion 189 is large enough to prevent movement of byproducts from corrosion, recess portion 189 may not need to penetrate planarization layer 180.

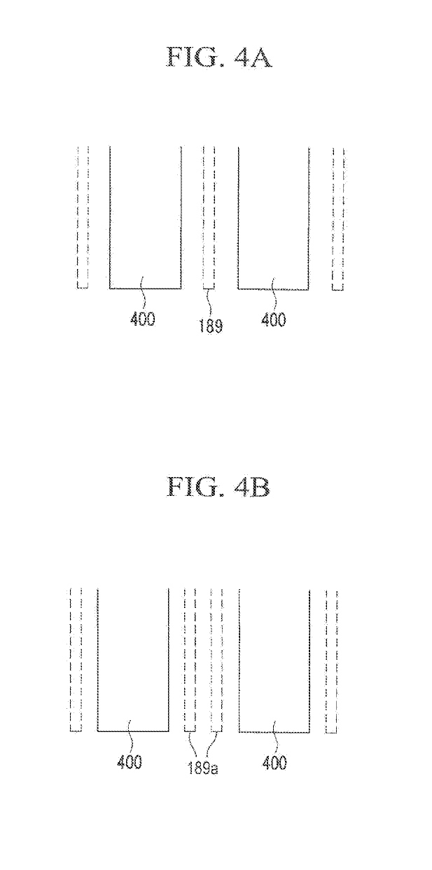

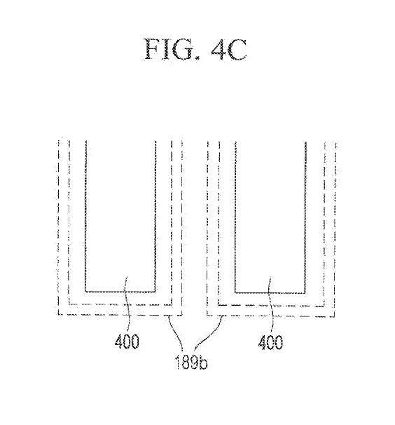

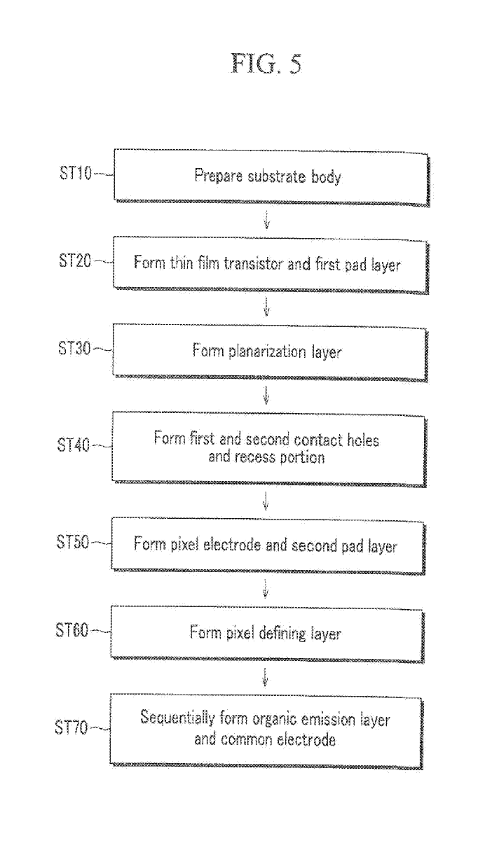

In the present exemplary embodiment, as shown in FIG. 4A, recess portion 189 has a line shape extending along the length direction of pad 400, and is provided as a single unit between neighboring pads 400.

The present invention is not, however, limited thereto. Thus, as shown in FIG. 4B, a plurality of recess portions 189a may be provided between neighboring pads 400. Alternatively, as shown in FIG. 4C, a recess portion 189b may be formed by being extended along three sides of pad 400. In this case, a movement path of the byproducts is lengthened and more steps are formed in the movement path so that the movement of the byproducts can be more effectively prevented.

Referring back to FIG. 3, in display area DA, pixel electrode 710 is formed on planarization layer 180 and pixel electrode 710 is connected to driving drain electrode 177 through first contact hole 181 of planarization layer 180. In pad area PA, second pad layer 420 is formed on first pad area 410 that is exposed by second contact hole 182 of planarization layer 180. Second pad layer 420 is formed through the same process as of pixel electrode 710, and may be formed with the same material at the same layer of pixel electrode 710.

In the present exemplary embodiment, pixel electrode 710 and second pad layer 420 may be formed with aluminum, silver, palladium, or copper. In further detail, pixel electrode 710 and second pad layer 420 may have a triple-layered structure with a silver layer, a palladium layer, and a copper layer stacked sequentially. When pixel electrode 710 and second pad layer 420 have the triple-layered structure, sulfuration of silver can be prevented and reflectance becomes much better than that of an aluminum-based material.

A pixel defining layer 190 covering pixel electrode 710 is formed in planarization layer 180. Pixel defining layer 190 has a first opening 199 exposing pixel electrode 710 and a second opening 198 exposing second pad layer 420 (or pad 400), and covers areas excluding first and second openings 198 and 199. In this case, pixel defining layer 190 is formed by filling recess portion 189 of planarization layer 180 formed in pad area PA. Pixel defining layer 199 may be formed with a polyacryl-based resin or a polyamide-based resin.

Organic emission layer 720 is formed above pixel electrode 710 within first opening 199 of pixel defining layer 190, and common electrode 730 is formed on pixel defining layer 190 and organic emission layer 720. Pixel electrode 710, organic emission layer 720, and common electrode 730 form OLED 70.

Organic emission layer 720 may be formed with a low molecular organic material or a high molecular organic material. Organic emission layer 720 may be formed of a multi-layered structure with at least one of an emission layer, a hole injection layer (HIL), a hole transport layer (HTL), an electron transport layer (ETL), and an electron injection layer (EIL). For example, if organic emissive layer 720 has all of the layers, the hole injection layer (HIL) is disposed on pixel electrode 710 being the positive electrode, and the hole transporting layer (HTL), the emissive layer, the electron transporting layer (ETL), and the electron injection layer (EIL) are sequentially stacked on the hole injection layer.

In the present exemplary embodiment, organic emission layer 720 is formed within opening 199 of pixel defining layer 190, but the present invention is not limited thereto. Thus, at least one of organic emission layer 720 may be formed not only on pixel electrode 710 within opening 199 of pixel defining layer 190, but also between pixel defining layer 190 and common electrode 730. In further detail, the hole injection layer (HIL), the hole transport layer (HTL), the electron transport layer (ETL), and the electron injection layer (EIL) of organic emission layer 720 may he formed in portions other than opening 199 by an open mask, and a light emission layer of organic emission layer 720 may be formed at each opening 199 through a fine metal mask (FMM).

Through second opening 198 of pixel defining layer 190, a flexible circuit board (FPC) (not shown) that is connected with an external circuit substrate and transmits an external signal therefore may be connected to pad 400. The flexible circuit board and pad 400 can be further smoothly connected with each other by forming the thickness of pixel defining layer 190 of pad area PA to be thinner than that of pixel defining layer 190 of display area DA.

In the present exemplary embodiment, recess portion 189 is formed between pads 400 to minimize movement of byproducts from the corrosion of pad 400. Accordingly, a short-circuit of pads 400 can be prevented and reliability of OLED display 100 can be improved.

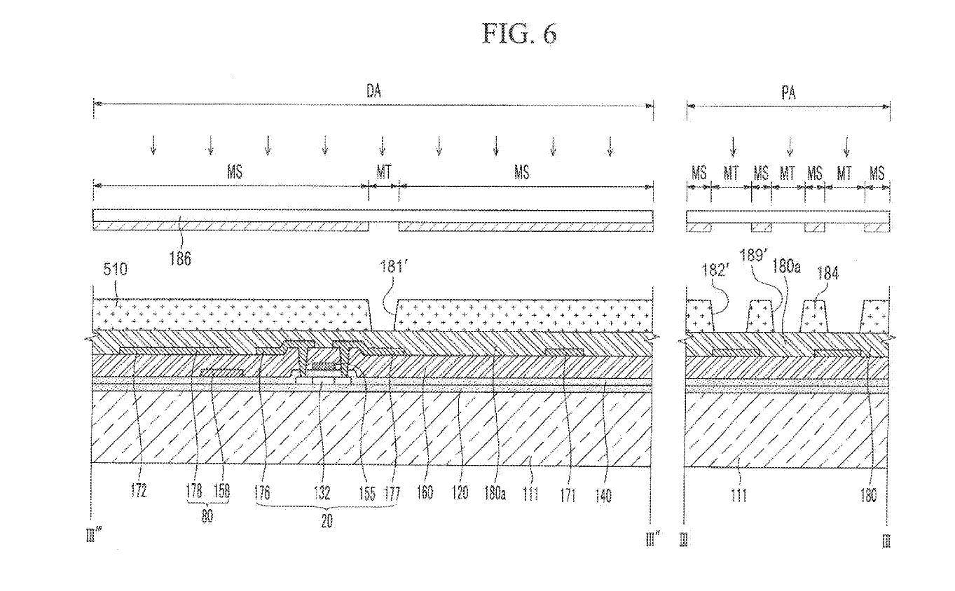

A manufacturing method of the OLED display according to the exemplary embodiment will now be described with reference to FIG. 3, FIG. 5, and FIG. 6. Hereinafter, a detailed description of the OLED display that has been described in the previous exemplary embodiment will be omitted.

FIG. 5 is a flowchart of a manufacturing method of the OLED display according to the exemplary embodiment, and FIG. 6 is a cross-sectional view of a process for forming the first and second contact holes and the recess portion in the planarization layer in the manufacturing method of the OLED display according to the exemplary embodiment.

Referring to FIG. 3 and FIG. 5, the manufacturing method of the OLED display as the present exemplary embodiment according to the principles of the present invention includes preparing a substrate body 111 including a display area DA and a pad area PA (ST10). Subsequently, a source electrode 176 and a drain electrode 177 of a thin film transistor 20 and a first pad layer 410 are formed in display area DA (ST20). A planarization layer 180 that covers source electrode 176, drain electrode 177, and first pad layer 410 is formed (ST30). First and second contact holes 181 and 182 respectively exposing drain electrode 177 and first pad layer 410 and a recess portion 189 disposed between first pad layers 410 are formed in planarization layer 180 (ST40). A pixel electrode 710 and a second pad layer 420 are respectively formed on first and second contact holes 181 and 182 (ST50). A pixel defining layer 190 having first and second openings 199 and 198 that expose pixel electrode 710 and a part of second pad layer 420 is formed (ST60). An organic emission layer 720 and a common electrode 730 are sequentially formed on first opening 199 of pixel defining layer 190 (ST70).

Processes other than the process for forming the first and second contact holes and the recess portion in the planarization layer can be performed using various well-known methods, and therefore no further description will be provided.

According to the present exemplary embodiment, in the step ST40, the contact holes and the recess portion may be formed in the planarization layer by forming a photosensitive pattern 184 using a mask 186 as shown in FIG. 6.

In the present exemplary embodiment, mask 186 includes a transparent section MT formed at a portion corresponding to first and second contact holes 181 and 182 and recess portion 189, and a light blocking section MS formed corresponding to other portions.

In step ST40 of forming first and second contact holes 181 and 182 and recess portion 189, first, a material for forming planarization layer 180a is formed to cover the entire surface of a substrate. A photosensitive material layer 510 is subsequently formed to cover an entire surface of planarization layer 180a. Then, mask 186 is arranged and aligned on the substrate, and the substrate and mask 186 are exposed to a light having predetermined energy. After the exposure, a developing process is performed on the substrate. The portion of the photosensitive material corresponding to transparent section MT is eliminated after the exposing and developing process, and the portion of the photosensitive material corresponding to light blocking section MS remains as photosensitive pattern 184. As a result, photosensitive material layer 510 is formed with photosensitive pattern 184 having a first contact hole pattern 181′, a second contact hole pattern 182′, and a recess portion pattern 189′. At last, planarization layer 180a with photosensitive pattern 184 is etched to form first contact hole 181, second contact hole 182, and recess portion pattern 189. As described, a photosensitive material of which a portion is eliminated when being exposed to light is used in the present exemplary embodiment, but the present invention is not limited thereto. That is, a photosensitive material may be used to eliminate a portion that is not exposed to light. In this case, transparent section MT and light blocking section MS are opposite to the mask of FIG. 6.

By using photosensitive pattern 184, a portion of planarization layer 180 corresponding to first and second contact holes 181 and 182 and recess portion 189 can be etched.

The depths of second contact hole 182 and recess portion 189 may be appropriately controlled by using a mask having a semi-transparent section (not shown) that partially blocks light and partially passes light. For example, recess portion 189 may have a depth that is larger than that of second contact hole 182 by locating the transparent section MT of mask 186 to correspond to recess portion 189 and locating the semi-transparent section of mask 186 to correspond to second contact hole 182. That is, recess portion 189 and second contact hole 182 may have desired depths by modifying locations of the transparent section and the semi-transparent section in mask 186. In other words, the depths of recess portion 189 and second contact hole 182 may be controlled by controlling degrees of transparency of the corresponding transparent section in mask 186.

That is, since first and second contact holes 181 and 182 and recess portion 189 can he simultaneously formed in planarization layer 180 by using a single mask, recess portion 189 that can prevent a short-circuit of pads 400 can be formed without an additional process.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

### DESCRIPTION OF SYMBOLS

100: organic light emitting diode (OLED) display
DA: display area
NDA: non-display area
180: planarization layer
182: contact hole
186: mask
189, 189a, 189b: recess portion
190: pixel defining layer
400: pad
410: first pad layer
420: second pad layer

What is claimed is:

1. An organic light emitting diode (OLED) display, comprising:
a substrate including a display area and a pad area;
an organic light emitting element formed in the display area;
a plurality of pads formed in the pad area, and receiving an external signal for light emission of the organic light emitting element and transmitting the signal to the organic light emitting element; and
a planarization layer insulating the pads,
the planarization layer comprising a recess portion formed between the pads.

2. The OLED display of claim 1, wherein the recess portion has a line shape extending along a length direction of one of the pads.

3. The OLED display of claim 2, wherein a single recess portion is formed between neighboring pads.

4. The OLED display of claim 2, wherein a plurality of recess portions are formed between neighboring pads.

5. The OLED display of claim 1, wherein the recess portion extends along three sides of the pad.

6. The OLED display of claim 1, wherein the recess portion is formed penetrating the planarization layer.

7. The OLED display of claim 1, further comprising a thin film transistor formed on the display area and including a semiconductor layer, a gate electrode, a source electrode, and a drain electrode,
wherein the organic light emitting element comprises a pixel electrode connected to the drain electrode through a first contact hole of the planarization layer, and
the pad comprises a first pad layer formed as the same layer with the source and drain electrode and a second pad layer formed as the same layer with the pixel electrode.

8. The OLED display of claim 7, wherein the planarization layer comprises a second contact hole exposing the first pad layer, and the second pad layer is formed on the first pad layer exposed by the second contact hole.

9. The OLED display of claim 7, further comprising a pixel defining layer having an opening that exposes the pixel electrode;
wherein the pixel defining layer fills the recess portion of the planarization layer.

10. The OLED display of claim 7, wherein the second pad layer is made from at least one material selected from a group consisting of aluminum, silver, palladium, and copper.

11. A manufacturing method of an organic light emitting diode (OLED) display, comprising:
preparing a substrate body including a display area and a pad area;
forming a source electrode and a drain electrode of a thin film transistor in the display area and a first pad layer in the pad area;
forming a planarization layer covering the source electrode, the drain electrode, and the first pad layer;
forming first and second contact holes respectively exposing the drain electrode and the first pad layer in the planarization layer; and
forming a pixel electrode and a second pad layer respectively on the first contact hole and the second contact hole,
the forming of the first and second contact holes comprises forming a recess portion between the first pads in the planarization layer.

12. The manufacturing method of claim 11, wherein the first contact hole, the second contact hole, and the recess portion are formed together through a process using a single mask.

13. The manufacturing method of claim 12, wherein a depth of the recess portion is controlled by controlling a degree of transparency of a portion of the single mask corresponding to the recess portion.

14. The manufacturing method of claim 11, further comprising, after the forming of the pixel electrode and the second pad layer:
forming a pixel defining layer having an opening that exposes the pixel electrode and the second pad layer; and
sequentially forming an organic emission layer and a common electrode on the opening of the pixel defining layer,
wherein the pixel defining layer fills the recess portion of the planarization layer.

15. The manufacturing method of claim 11, wherein the second pad layer is made from at least one material selected from a group consisting of aluminum, silver, palladium, and copper.
